(19) United States
(12) Patent Application Publication
(10) Pub. No.: US 2023/0238473 A1
(43) Pub. Date: Jul. 27, 2023

(54) Transfer member, preparation method thereof and transfer head having same

(71) Applicant: CHONGQING KONKA PHOTOELECTRIC TECHNOLOGY RESEARCH INSTITUTE CO., LTD., Chongqing (CN)

(72) Inventors: Tao WANG, Chongqing (CN); Yuanyuan CHAI, Chongqing (CN); Kai-yi WU, Chongqing (CN)

(21) Appl. No.: 17/611,914

(22) PCT Filed: Oct. 12, 2020
(86) PCT No.: PCT/CN2020/120489

§ 371 Date: Nov. 17, 2021

(51) Int. Cl. H01L 33/00

(52) U.S. Cl. CPC H01L 33/0062

(57) ABSTRACT

Related are a transfer member, a preparation method thereof and a transfer head having the same. The preparation method thereof includes the following operations: an inorganic substrate is provided, and a material for forming the inorganic substrate is selected from any one or more of a silicon-containing inorganic material, an III-V group compound semiconductor material, an II-VI group compound semiconductor material, and a metal material, herein, the hardness of metal is less than that of sapphire; a dry etching process is used to form a first microstructure on the surface of the inorganic substrate, to obtain a patterned substrate; an elastic glue layer is formed on a patterned surface of the patterned substrate, and the elastic glue layer has a second microstructure complementary to the first microstructure; the patterned substrate is removed, to obtain the transfer member.

### TECHNICAL FIELD

The present invention relates to the field of micro-nano processing technologies, and in particular to a transfer member, a preparation method thereof and a transfer head having the same.

### BACKGROUND

At present, Polydimethylsiloxane Stamp (PDMS Stamp) is a main device used for mass transfer of micro-devices, and there are few manufacturers on the market. Most of PDMS Stamps are usually produced and prepared according to a rollover method, including the following operations: a microstructure is formed on the surface of a sapphire substrate, and one side having the microstructure is covered with a layer of cured polydimethylsiloxane by injection forming, and then a base plate is bonded on the other side, elastic glue is separated from the sapphire substrate by a rollover process.

However, a depth-to-width ratio of the PDMS Stamp prepared by the above method is relatively small, and a height difference of a RGB three-color Light Emitting Diode (LED) is usually greater than 5 μm, and the PDMS with a depth of 10 μm is difficult to compensate for the height difference of the RGB three-color LED, so that a transfer yield of the LED is reduced.

### SUMMARY

In view of the above disadvantages of the prior art, a purpose of the present application is to provide a transfer member, a preparation method thereof and a transfer head having the same, and aim to solve a problem that a depth-to-width ratio of the transfer member formed by a preparation process in the prior art is small so that a transfer yield of LED is relatively low.

A preparation method for a transfer member is provided, including the following operations.

An inorganic substrate is provided, and a material forming the inorganic substrate is one or more materials selected from a silicon-containing inorganic material, an III-V group compound semiconductor material and a metal material, wherein the hardness of the metal material is less than a hardness of sapphire.

A dry etching process is used to form a first microstructure on the surface of the inorganic substrate, to obtain a patterned substrate.

An elastic glue layer is formed on a patterned surface of the patterned substrate, and the elastic glue layer has a second microstructure complementary to the first microstructure.

The patterned substrate is removed, to obtain the transfer member.

In the above preparation method for the transfer member of the present invention, the sapphire substrate in the prior art is replaced by the inorganic substrate, and the material for forming the inorganic substrate is one or more materials selected from the silicon-containing inorganic material, the III-V group compound semiconductor, the II-VI compound semiconductor and the metal, wherein the hardness of the metal is less than the hardness of sapphire. Because the dry etching process of the above inorganic substrate material such as gallium arsenide is mature, the process yield may be improved, and the cost of the process is reduced, and because the hardness of the above inorganic substrate material is smaller than the hardness of the sapphire substrate in the prior art, a larger depth-to-width ratio may be achieved under the same dry etching conditions, the transfer yield of the LED is improved; in addition, the above inorganic substrate material has high flatness in pits of the microstructure formed after the dry etching process, thereby the surface roughness of the transfer member may be effectively reduced.

Optionally, the silicon-containing inorganic material includes glass.

Optionally, the III-V group compound semiconductor material includes gallium arsenide or gallium phosphide.

Optionally, the metal material is an alloy formed by any one or more metals selected from aluminum, copper, germanium, and titanium.

The inorganic substrate formed by using the above materials may not only achieve a larger etching depth-to-width ratio in the dry etching process, but also have a higher etching uniformity, so that an inner wall of the first microstructure obtained by etching has the higher flatness.

Optionally, the operation of forming the first microstructure on the surface of the inorganic substrate includes: the surface of the inorganic substrate is covered with a photoresist layer, and a photolithography process is used to pattern the photoresist layer; the patterned photoresist layer is used as a mask for dry-etching the inorganic substrate, and then the photoresist layer is removed, to obtain the patterned substrate with the first microstructure.

Optionally, the first microstructure constitutes protrusions positioned on the surface of the patterned substrate, the protrusions are distributed in an array, and a cross section, perpendicular to the surface of the inorganic substrate, of each of the protrusions is rectangular or trapezoidal. The above inorganic substrate of the present invention is used in combination with the dry etching process, through adjusting process conditions such as an etching rate and a gas flow in the etching process, the vertical cross sections of the protrusions in the first microstructure obtained may have a variety of shapes, thereby a shape of the transfer member finally obtained is varied.

Optionally, a height of the first microstructure is 50 μm˜300 μm. The sapphire substrate used in the prior art is more difficult to etch, and an etching depth is usually less than 10 μm, so that a depth of the prepared transfer member is also less than 10 μm. A height difference of a RGB three-color LED is usually greater than 5 μm, and the transfer member with the depth of 10 μm is more difficult to compensate for the height difference of the LED, so the transfer yield is reduced. Compared with the above sapphire substrate in the prior art, the material for forming the inorganic substrate of the present invention may have a smaller hardness, so that a larger depth-to-width ratio may be achieved under the same dry etching conditions, thereby the height difference of the LED may be effectively compensated, and the transfer yield is guaranteed.

Optionally, an etching temperature of the dry etching process is 18° C.˜22° C.

Optionally, a plasma etching power of the dry etching process is 140 W˜160 W, and a working pressure of the dry etching process is 0.4 mT˜0.6 mT.

The above dry etching process conditions are used, not only a larger etching rate may be achieved, but also the first microstructure with the larger depth-to-width ratio may be obtained.

Optionally, an etching gas of the dry etching process includes chlorine gas and/or boron trichloride. The above etching gas may be used to improve the effect of dry etching on gallium arsenide.

Optionally, the elastic glue layer is formed on the patterned surface by using an injection forming process. The injection forming process may be used to have a higher curing efficiency.

Optionally, the operation of removing the patterned substrate includes: a first base plate is adhered on one side, away from the patterned substrate, of the elastic glue layer; the patterned substrate is removed by using a wet etching process, so that the elastic glue layer is transferred to the first base plate. Because the hardness of the elastic glue layer is small and the elastic glue layer usually has a thinner thickness, through first adhering a base plate on the other side of the elastic glue layer, it may not only be used to support the elastic glue layer, but also may be beneficial to the removal of the patterned substrate.

Optionally, the material forming the inorganic substrate is gallium arsenide, and an etching solution of the wet etching process includes ammonia water and hydrogen peroxide. The above etching solution may be used to improve the wet etching effect on gallium arsenide.

Optionally, the glass includes one or more of silicate glass, borate glass, and phosphate glass.

Optionally, the elastic glue layer includes polydimethylsiloxane cured layer.

Based on the same inventive concept, the present invention also provides a transfer member, and the transfer member is prepared by the above method. Because the hardness of the inorganic substrate used in the above preparation method is smaller than the hardness of the sapphire substrate in the prior art, the larger depth-to-width ratio may be achieved under the same dry etching conditions, thereby the LED transfer yield is improved, and the above inorganic substrate material has the high flatness in the pits of the microstructure formed after the dry etching process, so that the surface roughness of the transfer member may be effectively reduced.

Based on the same inventive concept, the present invention also provides a transfer head, the transfer head includes the above transfer member. Because the above transfer head includes the transfer member prepared by the above method, it may not only improve the transfer yield of the LED, but also have a lower surface roughness.

### BRIEF DESCRIPTION OF THE DRAWINGS

FIG. 1 is a structure schematic diagram of an inorganic substrate provided in a preparation method for a transfer member provided according to an embodiment of the present invention;

FIG. 2 is a structure schematic diagram of a base after covering the surface of the inorganic substrate shown in FIG. 1 with a photoresist layer;

FIG. 3 is a structure schematic diagram of a base during a dry etching process of the inorganic substrate by using the patterned photoresist layer shown in FIG. 2 as a mask;

FIG. 4 is a structure schematic diagram of a base after performing the dry etching process on the inorganic substrate by using the patterned photoresist layer shown in FIG. 3 as a mask to obtain a first microstructure;

FIG. 5 is a structure schematic diagram of the patterned substrate after the photoresist layer shown in FIG. 4 is removed;

FIG. 6 is a structure schematic diagram of a base after an elastic glue layer is formed on a patterned surface of the patterned substrate shown in FIG. 5;

FIG. 7 to FIG. 9 are structure schematic diagrams of a base after a first base plate is adhered to one side, away from the patterned substrate, of the elastic glue layer shown in FIG. 6; and

FIG. 10 to FIG. 12 are structure schematic diagrams of a base after the patterned substrate shown in FIG. 7 is removed.

### DESCRIPTIONS OF REFERENCE SIGNS

10-Inorganic substrate; 110-First microstructure; 120-Patterned substrate; 20-Photoresist layer; 30-Elastic glue layer; 310-Second microstructure; and 40-First base plate.

### DETAILED DESCRIPTION OF THE EMBODIMENTS

In order to understand the present application conveniently, the present application is more comprehensively described below with reference to related drawings. Preferred implementation modes of the present application are shown in the drawings. However, the present application may be implemented in many different forms and is not limited to the implementation modes described herein. On the contrary, a purpose of providing these implementation modes is to make the understanding of the disclosed content of the present application more thorough and comprehensive.

Unless otherwise defined, all technical and scientific terms used herein have the same meaning as commonly understood by those skilled in the art of the present application. Terminologies used in the description of the present application herein are only for a purpose of describing the specific implementation modes, and are not intended to limit the present application.

As described in the background, the existing preparation method for preparing the polydimethylsiloxane stamp not only has the high production cost, but also the prepared and formed PDMS Stamp has the small depth-to-width ratio; the above method may also easily cause the microstructure to produce an internal erosion phenomenon during etching, so that the substrate is more difficultly separated from the PDMS, and demolding is difficult so that the transfer yield is reduced; in addition, the above method easily leads to unevenness of the surface of the stamp, so that an adhesion force is reduced.

In order to solve the above problems, the present invention provides a preparation method for a transfer member, including the following operations.

An inorganic substrate is provided, and a material forming the inorganic substrate is one or more materials selected from a silicon-containing inorganic material, an III-V group compound semiconductor material and a metal material, wherein the hardness of the metal is less than the hardness of sapphire.

A dry etching process is used to form a first microstructure on the surface of the inorganic substrate, to obtain a patterned substrate;

An elastic glue layer is formed on a patterned surface of the patterned substrate, and the elastic glue layer has a second microstructure complementary to the first microstructure.

The patterned substrate is removed, to obtain the transfer member.

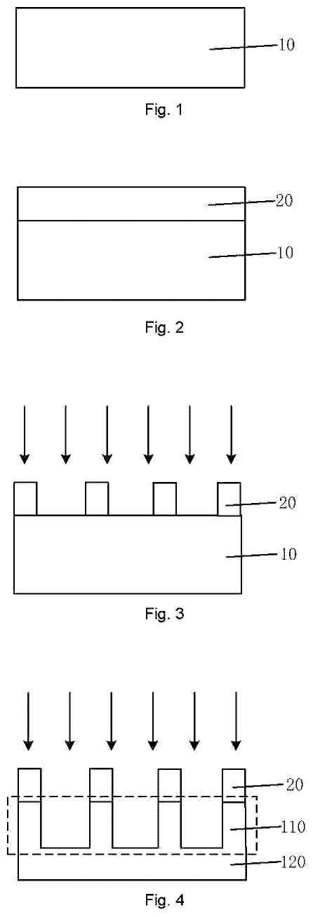

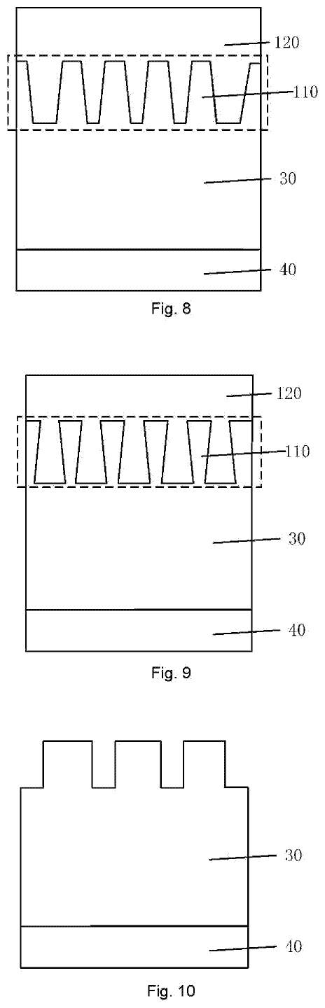

Exemplary implementation modes of the preparation method for the transfer member provided according to the present invention are described below in more detail with reference to FIGS. 1 to 8. However, these exemplary implementation modes may be implemented in a variety of different forms, and should not be explained as being limited to the implementation modes described herein. It should be understood that these implementation modes are provided to make the disclosure of the present invention thorough and complete, and to fully convey concepts of these exemplary implementation modes to those of ordinary skill in the art.

Firstly, the inorganic substrate 10 is provided. As shown in FIG. 1, the material for forming the inorganic substrate 10 is one or more materials selected from the silicon-containing inorganic material, the III-V group compound semiconductor material, and the metal material, wherein the hardness of the metal material is less than the hardness of sapphire.

In some implementation modes, the above silicon-containing inorganic material includes glass, such as silicate glass, borate glass, and phosphate glass.

In some implementation modes, the above III-V group compound semiconductor material includes gallium arsenide or gallium phosphide.

In some implementation modes, the above metal material is an alloy formed by any one or more metals selected from aluminum, copper, germanium, and titanium.

After the above operation of providing the inorganic substrate 10, the dry etching process is used to form the first microstructure 110 on the surface of the inorganic substrate 10, to obtain a patterned substrate 120, as shown in FIG. 2 to FIG. 5.

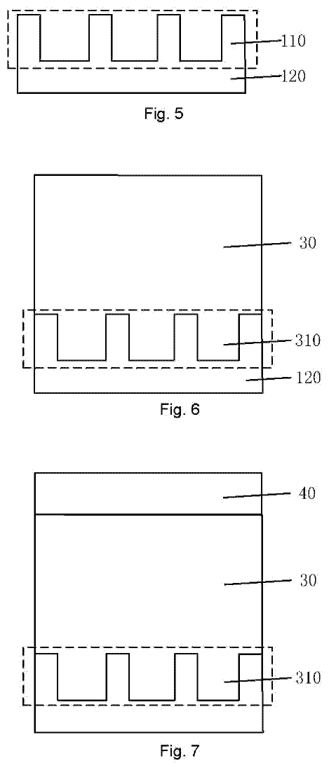

In some implementation modes, the operation of forming the above first microstructure 110 on the surface of the inorganic substrate 10 includes: the surface of the inorganic substrate 10 is covered with a photoresist layer 20, and a photolithography process is used to pattern the photoresist layer 20, as shown in FIG. 2 and FIG. 3; the patterned photoresist layer 20 is used as a mask for dry-etching the inorganic substrate 10, and then the photoresist layer 20 is removed, to obtain a patterned substrate 120 with the first microstructure 110, as shown in FIG. 4 and FIG. 5.

In some implementation modes, the above first microstructure 110 constitutes protrusions positioned on the surface of the patterned substrate 120, the protrusions are distributed in an array, and a cross section, perpendicular to the surface of the inorganic substrate 10, of each of the protrusions is rectangular or trapezoidal.

In the above implementation modes, through adjusting process conditions such as an etching rate and a gas flow in the etching process, the vertical cross sections of the protrusions in the first microstructure 110 obtained may have a variety of shapes, thereby a shape of the transfer member finally obtained is varied.

In the above implementation modes, a height of the first microstructure 110 may be 50 μm˜300 μm. The sapphire substrate used in the prior art is more difficult to etch, and an etching depth is usually less than 10 μm, so that a depth of the prepared transfer member is also less than 10 μm. A height difference of a RGB three-color LED is usually greater than 5 μm, and the transfer member with the depth of 10 μm is more difficult to compensate for the height difference of the LED, so the transfer yield is reduced. Compared with the above sapphire substrate in the prior art, the material for forming the inorganic substrate 10 of the present invention may have a smaller hardness, so that a larger depth-to-width ratio may be achieved under the same dry etching conditions, thereby the height difference of the LED may be effectively compensated, and the transfer yield is guaranteed.

In some implementation modes, an etching temperature of the above dry etching process is 18° C.˜22° C., a plasma etching power of the dry etching process is 140 W˜160 W, and a working pressure of the dry etching process is 0.4 mT˜0.6 mT. The above dry etching process conditions are used, not only a larger etching rate may be achieved, but also the first microstructure 110 with the larger depth-to-width ratio may be obtained.

In order to further improve the dry etching effect on gallium arsenide, in some implementation modes, an etching gas of the above dry etching process includes chlorine gas and/or boron trichloride.

After the operation that the patterned substrate 120 having the first microstructure 110 is obtained, an elastic glue layer 30 is formed on a patterned surface of the patterned substrate 120, and the elastic glue layer 30 has a second microstructure 310 complementary to the first microstructure 110, as shown in FIG. 6.

Illustratively, the above elastic glue layer 30 is a polydimethylsiloxane cured layer, and the transfer member obtained by the above preparation method of the present invention is a polydimethylsiloxane stamp.

In some implementation modes, the above elastic glue layer 30 is formed on the patterned surface by using an injection forming process. Those skilled in the art may reasonably set conditions of the above injection forming process according to the prior art, it is not repeatedly described here.

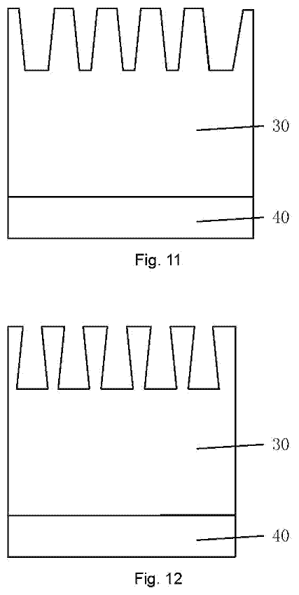

After the operation of forming the elastic glue layer 30 having the second microstructure 310, the patterned substrate 120 is removed, to obtain the transfer member, as shown in FIG. 7 to FIG. 12.

In some implementation modes, the operation of removing the above patterned substrate 120 includes: a first base plate 40 is adhered on one side, away from the patterned substrate 120, of the elastic glue layer 30, while the vertical cross sections of protrusions in the above first microstructure 110 are rectangular, regular trapezoid, and inverted trapezoid respectively, the structures shown in FIG. 7 to FIG. 9 may be achieved after the above operation respectively; the patterned substrate 120 is removed by a wet etching process, so that the elastic glue layer 30 is transferred to the first base plate 40, while the vertical cross sections of protrusions in the above first microstructure 110 are rectangular, regular trapezoid, and inverted trapezoid, the structures shown in FIG. 10 to FIG. 12 are respectively obtained after the above operation.

In the above implementation modes, because the hardness of the elastic glue layer 30 is relatively small, and the elastic glue layer 30 usually has a thinner thickness, by firstly adhering a base plate on the other side of the elastic glue layer 30, it may not only be used for supporting the elastic glue layer 30, but also beneficial to the removal of the patterned substrate 120.

In the above implementation modes, the material for forming the inorganic substrate 10 may be gallium arsenide. In this case, in order to improve the wet etching effect on gallium arsenide, etching solution used in the wet etching process may include ammonia and hydrogen peroxide.

Based on the same inventive concept, the present invention also provides a transfer member, the transfer member is prepared by the above method.

Based on the same inventive concept, the present invention also provides a transfer head, and the transfer head includes the above transfer member.

It should be understood that applications of the present invention are not limited to the above examples, improvements or changes may be made by those of ordinary skill in the art according to the above descriptions, and all these improvements and changes should fall within a scope of protection of the appended claims of the present invention.

What is claimed is:

1. A preparation method for a transfer member, comprising the following operations:
providing an inorganic substrate, wherein a material forming the inorganic substrate is one or more materials selected from a silicon-containing inorganic material, an III-V group compound semiconductor material and a metal material, wherein, a hardness of the metal material is less than a hardness of sapphire;
forming a first microstructure on a surface of the inorganic substrate by using a dry etching process, to obtain a patterned substrate;
forming an elastic glue layer on a patterned surface of the patterned substrate, wherein the elastic glue layer has a second microstructure complementary to the first microstructure; and
removing the patterned substrate, to obtain the transfer member.

2. The preparation method according to claim 1, wherein the silicon-containing inorganic material comprises glass.

3. The preparation method according to claim 1, wherein the III-V group compound semiconductor material comprises gallium arsenide or gallium phosphide.

4. The preparation method according to claim 1, wherein the metal material is an alloy formed by any one or more metals selected from aluminum, copper, germanium, and titanium.

5. The preparation method according to claim 1, wherein the operation of forming the first microstructure on the surface of the inorganic substrate comprises:
covering the surface of the inorganic substrate with a photoresist layer, and patterning the photoresist layer by using a photolithography process; and
dry-etching the inorganic substrate by using the patterned photoresist layer as a mask, and then removing the photoresist layer, to obtain the patterned substrate having the first microstructure.

6. The preparation method according to claim 1, wherein the first microstructure constitutes protrusions positioned on the surface of the patterned substrate, the protrusions are distributed in an array, and a cross section, perpendicular to the surface of the inorganic substrate, of each of the protrusions is rectangular or trapezoidal.

7. The preparation method according to claim 6, wherein a height of the first microstructure is 50 μm˜300 μm.

8. The preparation method according to claim 1, wherein an etching gas of the dry etching process comprises chlorine gas and/or boron trichloride.

9. The preparation method according to claim 8, wherein an etching temperature of the dry etching process is 18° C.˜22° C.

10. The preparation method according to claim 8, wherein a plasma etching power of the dry etching process is 140 W˜160 W, and a working pressure of the dry etching process is 0.4 mT˜0.6 mT.

11. The preparation method according to cliam 1, wherein the elastic glue layer is formed on the patterned surface by using an injection forming process.

12. The preparation method according to claim 1, wherein the operation of removing the patterned substrate comprises:
adhering a first base plate on one side, away from the patterned substrate, of the elastic glue layer; and
removing the patterned substrate by using a wet etching process, so as to transfer the elastic glue layer to the first base plate.

13. The preparation method according to claim 12, wherein the material forming the inorganic substrate is gallium arsenide, and an etching solution of the wet etching process comprises ammonia water and hydrogen peroxide.

14. A transfer member, wherein the transfer member is prepared by a preparation method, the preparation method comprises the following operations:
providing an inorganic substrate, wherein a material for forming the inorganic substrate is one or more materials selected from a silicon-containing inorganic material, an III-V group compound semiconductor material and a metal material, wherein, a hardness of the metal material is less than a hardness of sapphire;
forming a first microstructure on the surface of the inorganic substrate by using a dry etching process, to obtain a patterned substrate;
forming an elastic glue layer on a patterned surface of the patterned substrate, wherein the elastic glue layer has a second microstructure complementary to the first microstructure; and
removing the patterned substrate, to obtain the transfer member.

15. A transfer head, comprising a transfer member, wherein the transfer member is prepared by a preparation method, the preparation method comprises the following operations:
providing an inorganic substrate, wherein a material for forming the inorganic substrate is one or more materials selected from a silicon-containing inorganic material, an III-V group compound semiconductor material and a metal material, wherein, a hardness of the metal material is less than a hardness of sapphire;
forming a first microstructure on the surface of the inorganic substrate by using a dry etching process, to obtain a patterned substrate;
forming an elastic glue layer on a patterned surface of the patterned substrate, wherein the elastic glue layer has a second microstructure complementary to the first microstructure; and
removing the patterned substrate, to obtain the transfer member.

16. The transfer member according to claim 14, wherein the silicon-containing inorganic material comprises glass.

17. The transfer member according to claim 14, wherein the III-V group compound semiconductor material comprises gallium arsenide or gallium phosphide.

18. The transfer head according to claim 15, wherein the silicon-containing inorganic material comprises glass.

19. The preparation method according to claim 2, wherein the glass comprises one or more of silicate glass, borate glass, and phosphate glass.

20. The preparation method according to claim 1, wherein the elastic glue layer comprises polydimethylsiloxane cured layer.
